(19) United States
(12) Patent Application Publication
(10) Pub. No.: US 2015/0247891 A1
(43) Pub. Date: Sep. 3, 2015

(54) Detection of High Impedance Faults

(71) Applicants: Jean-Claude Maun, B-Bruessel (BE); Alicia Valero Masa, Bilbao (ES)

(72) Inventors: Jean-Claude Maun, B-Bruessel (BE); Alicia Valero Masa, Bilbao (ES)

(21) Appl. No.: 14/427,694

(22) PCT Filed: Sep. 12, 2012
(86) PCT No.: PCT/EP2012/067838

§ 371 Date: Apr. 7, 2015

(51) Int. Cl. G01R 31/02; G01R 31/40

(52) U.S. Cl. CPC G01R 31/025; G01R 31/40

(57) ABSTRACT

A method detects a high-impedance fault occurring in an electric distribution circuit that distributes a three-phase alternating current. The method includes the steps of applying a plurality of electrical signal analysis techniques that provide a plurality of fault detection indicators, and generating a signal that indicates a high-impedance fault depending on the outcome of the fault detection indicators. The method is characterized by determining a randomness of the residual current of the three-phase alternating current prior to determining the plurality of fault detection indicators, and generating a trigger signal depending on the randomness of the residual current. The step of determining the plurality of fault detection indicators requires that the trigger signal has been generated.

The invention described below was developed in the context of a collaboration between Siemens AG and the faculty of Applied Sciences Bio-, Electro- and Mechanical Systems at the Free University of Brussels ULB (Université Libre de Bruxelles) under the Leadership of Professor Maun.

The invention relates to methods and devices for detecting High Impedance Faults (HIF) occurring in an electric distribution circuit that distributes a three-phase alternating current.

### BACKGROUND OF THE INVENTION

The publication “Field Experience with High-Impedance Fault Detection Relays” (Alvin C. Depew, Jason M. Parsick, Robert W. Dempsey, Carl L. Benner, B. Don Russell, Mark G. Adamiak, 2006 IEEE) describes the efforts made by the Potomac Electric Power Company to reliably detect high-impedance faults.

The international patent application WO 95/10815 discloses a method of detecting high-impedance faults in further detail. A plurality of electrical signal analysis techniques is applied that provide a number of fault indicators. Depending on the outcome of said fault detection indicators a signal indicating a high-impedance fault is generated or not.

Under certain conditions the current of High Impedance Faults is lower than the residual current during normal operation of the network; hence overcurrent devices do not detect this fault. The difficulty of the detection depends on the configuration of the network, the worst being the multi-grounded distribution systems, which are the most common systems in America.

Solidly grounded distribution systems in Europe are grounded at a single point, the substation. This practice together with the use of three-phase transformers in the MV/LV substations means that the neutral conductor under normal conditions carries barely a few amperes. In contrast, the typical configuration in America are multi-grounded systems using single-phase distribution transformers. This practice means that the current unbalance due to load switching is transferred to the primary distribution system, producing important neutral current. The stray current consequence of the multiple-grounding also contributes in the level of neutral current.

The residual current in multiple-grounded systems (America), is higher than in other configurations (in Europe). The settings of the overcurrent protections are 10 or 50 times less sensitive than in protections in Europe, thus the HIF detection is more difficult, and it cannot be performed by the same detection functions (overcurrent technology).

### OBJECTIVE OF THE PRESENT INVENTION

In view of the above, an objective of the present invention is to provide a method and a device that reliably indicate a possible High Impedance Fault and avoid additional efforts in data analysing if a High Impedance Fault seems unlikely.

### BRIEF SUMMARY OF THE INVENTION

An embodiment of the invention relates to a method of detecting a high-impedance fault occurring in an electric distribution circuit that distributes a three-phase alternating current, the method comprising the steps of applying a plurality of electrical signal analysis techniques that provide a number of fault indicators, and generating a signal that indicates a high-impedance fault depending on the outcome of said fault detection indicators. The method further comprises the steps of determining the randomness of the residual current of said three-phase alternating current prior to determining said plurality of fault detection indicators, and generating a trigger signal depending on the randomness of the residual current, wherein determining said plurality of fault detection indicators requires that said trigger signal has been generated.

An advantage of the present invention is that a time-consuming application of the plurality of electrical signal analysis techniques may be avoided if the occurrence of a high-impedance fault seems unlikely. To this end, the method analyzes the randomness of the residual current prior to applying the electrical signal analysis techniques and prior to determining the plurality of fault detection indicators. Depending on the randomness of the residual current, a trigger signal is generated or not. The further evaluation including the determination of said plurality of fault detection indicators may then be limited to cases when the trigger signal indicates a sufficient likelihood of the occurrence of a high-impedance fault.

A further advantage of the present invention is that it addresses the drawbacks of multiple-grounded distribution networks like those presently used in America.

According to a preferred embodiment, a randomness value (hereinafter also referred to as “AAD”) is calculated that describes the randomness of the residual current. Then, the trigger signal may be generated depending on the randomness value.

Further, a first threshold value (hereinafter also referred to as “AAD_threshold”) may be calculated based on a given number of cycles that preceded the actual cycle wherein generating said trigger signal requires that said randomness value exceeds said first threshold value.

Moreover, a second threshold value (hereinafter also referred to as “rand_AAD”) that describes the average randomness of the residual current before the actual trigger cycle (during normal operation without high-impedance fault) may be calculated, wherein generating said trigger signal requires that said randomness value exceeds said second threshold value.

Preferably, generating the trigger signal requires that said randomness value exceeds said first and second threshold value.

Furthermore, generating the trigger signal may also require that a reference value (hereinafter also referred to as “normal_AAD”) that indicates the average randomness of the residual current during normal conditions falls below a maximum randomness threshold value (hereinafter also referred to as “THLDₙₙₒᵣₘₐₗ_{_{—}}_{AAD}”) before the actual trigger cycle.

In the latter case, the trigger signal is preferably generated if said randomness value exceeds said first and second threshold value and the average randomness of the residual current falls below the maximum randomness threshold value.

Preferably, the method also includes the steps of evaluating the increase of each phase current of said three-phase alternating current in response to the generation of said trigger signal, and determining that no high-impedance fault occurred if all three-phases of said three-phase alternating current exhibit a similar increase of current before or after the generation of said trigger signal. In most cases, high-impedance faults are very unlikely if all three phases of the three-phase alternating current show a similar behaviour.

Further, an average difference value (hereinafter also referred to as “Iextr”) may be calculated by subtracting a previous average residual current value that defines the average residual current before the generation of said trigger signal, from an actual residual current value that defines the average current after the generation of said trigger signal.

The plurality of fault detection indicators is preferably determined if said trigger signal has been generated and the average difference value is between a predefined lower threshold value and a predefined upper threshold value.

A counter may be incremented if said trigger signal is generated and the average difference value exceeds the predefined upper threshold value.

The plurality of fault detection indicators is preferably determined if said trigger signal is generated and the counter reading equals or exceeds a predefined maximum count.

An further embodiment of the invention relates to a high-impedance fault detector capable of detecting a high-impedance fault occurring in an electric distribution circuit that distributes a three-phase alternating current, the detector comprising a computer being programmed to carry out the steps of: applying a plurality of electrical signal analysis techniques that provide a number of fault indicators, and generating a signal that indicates a high-impedance fault depending on the outcome of said fault detection indicators, wherein the randomness of the residual current (3I0) of said three-phase alternating current is determined prior to determining said plurality of fault detection indicators, wherein a trigger signal is generated depending on the randomness of the residual current, and wherein determining said plurality of fault detection indicators requires that said trigger signal has been generated.

### BRIEF DESCRIPTION OF THE DRAWINGS

In order that the manner in which the above-recited and other advantages of the invention are obtained will be readily understood, a more particular description of the invention briefly described above will be rendered by reference to specific embodiments thereof which are illustrated in the appended drawings. Understanding that these drawings depict only typical embodiments of the invention and are therefore not to be considered to be limiting of its scope, the invention will be described and explained with additional specificity and detail by the use of the accompanying drawings in which

FIG. 1 shows an exemplary embodiment of a high-impedance fault detector, and

FIG. 2 shows a flow diagram of an exemplary embodiment of a method for detecting a high-impedance fault.

### DETAILED DESCRIPTION OF THE PREFERRED EMBODIMENT

The preferred embodiment of the present invention will be best understood by reference to the drawings, wherein identical or comparable parts are designated by the same reference signs throughout.

It will be readily understood that the present invention, as generally described and illustrated in the figures herein, could vary in a wide range. Thus, the following more detailed description of the exemplary embodiments of the present invention, as represented in the figures, is not intended to limit the scope of the invention, as claimed, but is merely representative of presently preferred embodiments of the invention.

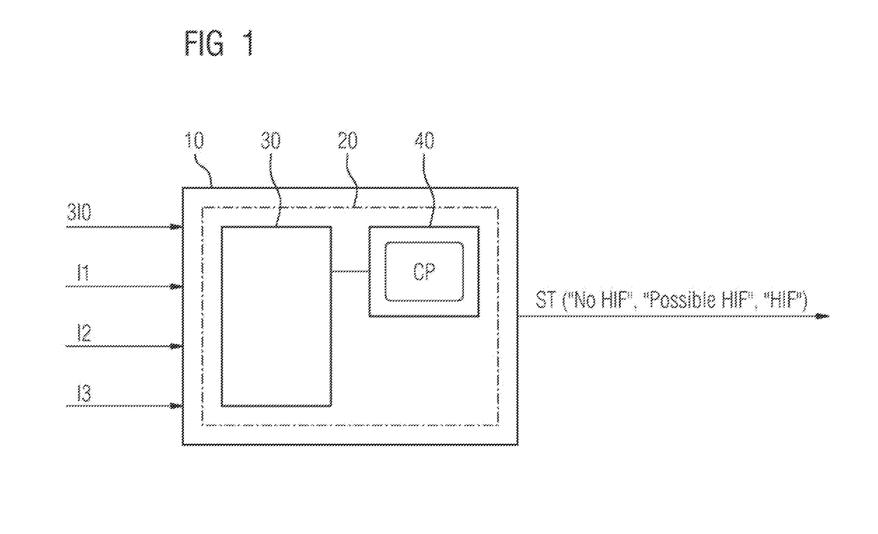

FIG. 1 shows an embodiment of a high-impedance fault detector 10. The detector 10 comprises a computer 20 having a microprocessor unit 30 and a memory 40. The memory 40 stores a computer program CP that may be carried out by the microprocessor unit 30 in order to detect a high-impedance fault occurring in an electric distribution circuit.

The detector 10 analyzes the residual current 3I0 and the 3-phase currents I1, I2, I3 of a three-phase alternating current and generates a signal ST indicating whether a high-impedance fault is likely (“HIF”), possible (“Possible HIF”) or unlikely (“No HIF”).

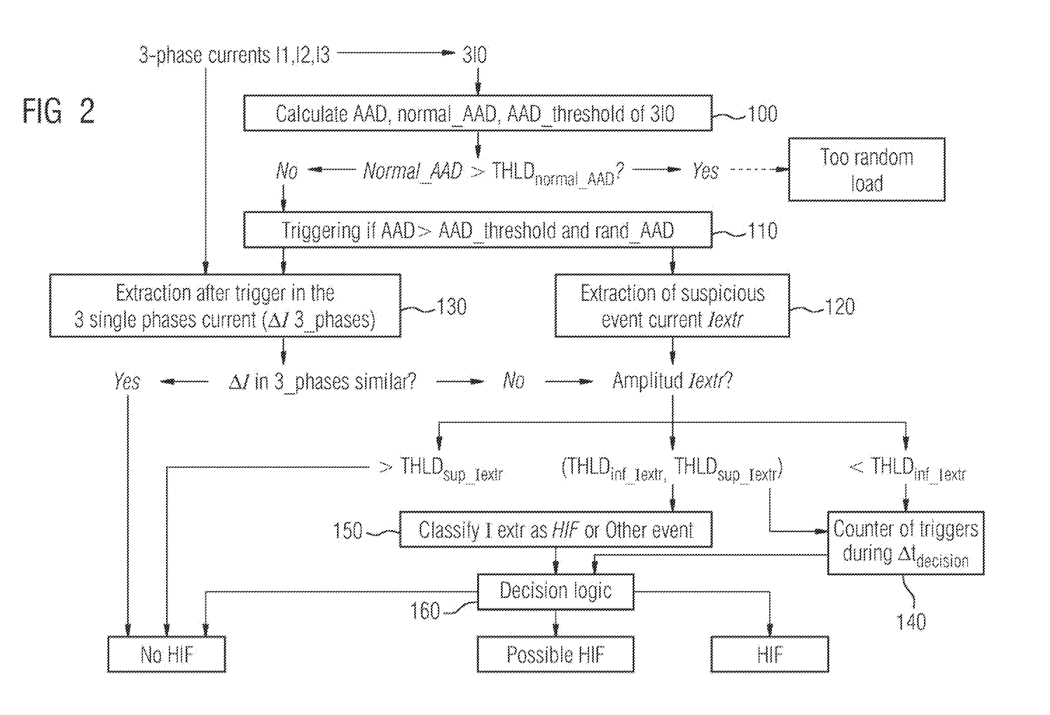

An exemplary embodiment of an algorithm that may be applied by the detector 10 of FIG. 1 is depicted in further detail in FIG. 2. The algorithm uses the three phase currents I1-I3 and outputs the label of “HIF”, “No HIF”, or “Possible HIF”.

If a high-impedance fault appears, an increase of randomness is expected, thus the algorithm monitors the randomness (see step 100 in FIG. 2) and triggers when there is an important increase (see step 110 in FIG. 2). To this end, the current of the high-impedance fault is superposed to the residual current of the pre-fault situation, thus the algorithm removes the current before the trigger from the current after the trigger so the extracted current is the current of the event that produced the trigger (possibly a HIF, see step 110 in FIG. 2). The extracted current is analyzed and classified as “HIF” or as “Other event”. Apart from this process there are other criteria that complement the algorithm. The final decision is made using information accumulated during a pre-defined period of time Δt decision. A complete description of the algorithm is presented hereinafter in further detail.

The inputs to the algorithm are the 3-phase currents I1-I3 and, if available, the sensitive measure of the residual current 3I0. If the residual current 3I0 is not directly available it is calculated by the sum of the 3-phase currents I1-I3.

A randomness value AAD is computed for the residual current 3I0, as well as a first threshold value AAD_threshold and a second threshold value rand_AAD. The second threshold value rand_AAD is calculated based on a reference value normal_AAD that defines the average randomness of the residual current 3I0 during normal operation (see step 100 in FIG. 2). These magnitudes measure, respectively, the instantaneous randomness of the residual current 3I0, the randomness of the residual current 3I0 under normal conditions of the network, the level above which the residual current 3I0 is considered random and the level above which the algorithm triggers. The definitions and expressions of each magnitude are shown in the following Table 1 which includes definitions and expressions of the magnitudes used in the description of the algorithm:

| Acronym | Meaning | Description/Equation |
|---|---|---|
| 3I0 | Residual Current | The sum of the 3phase current |
| AAD | Accumulated | AAD measure the randomness |
| | Absolute | of the signal by quantifying |
| | Differences cycle | the changes in the amplitude |
| | per cycle | and the content of |
| | | non-harmonic components |
| | | $AAD = {\sum }_{k = i}^{Nacc} \vert 3 I {0}_{k} - 3 I {0}_{k + spc} \vert$ |
| Nacc | Number of samples | Nacc determine the number |
| | accumulated | of differences cycle per |
| | | cycle that are accumulated |
| | | for calculating the AAD. |
| spc | Samples per cycle | |
| normal_AAD | Value of AAD when | It represents the randomness |
| | the network | of the residual current |
| | works under normal | 3I0 during normal operation |
| | conditions | of the network. It is calculated |
| | | as the average of AAD during |
| | | 20 cycles during which the |
| | | algorithm does not trigger. |
| rand_AAD | Minimum AAD | Value of AAD above which |
| | indicating | the signal is considered |
| | randomness | random. It depends on |
| | | normal_AAD: |
| | | if normal_AAD <= |
| | | C₁ * spc * Nacc, rand_AAD = |
| | | C₂ * spc * Nacc |
| | | if normal_AAD> |
| | | C₁ * spc * Nacc, rand_AAD = |
| | | normal_AAD * 2.5 C₁ = 1, |
| | | 25E-4; C₂ = 3, 125E-4 |
| THLD _{normal AAD} | Threshold that | THLD normal_AAD indicates |
| | indicates the | the maximum level of |
| | superior limit for | normal_AAD that allows |
| | normal_AAD | the algorithm to work |
| | | correctly. Above this value, |
| | | the randomness of the |
| | | residual current 3I0 under |
| | | normal conditions is too |
| | | random and the algorithm |
| | | cannot work. |
| | | THLD_{normal AAD} = C₃; C₃ = |
| | | 1E-3 * spc * Nacc |
| AADmean | mean value of AAD | AADmean is calculated each |
| | during 5 cycles | 5 cycles as the average |
| | | value during this period |
| AAD_Threshold | Threshold for AAD | It is a dynamic threshold, |
| | that determines | updated each 5 cycles, |
| | when the algorithm | which value is calculated |
| | triggers | based on the avarage |
| | | value of AAD during the |
| | | previous 5 cycles |
| | | Thresholdⱼ = C₄ * AADmeanⱼ₋₁; |
| | | C₄ = 1, 4 |
| ΔI 3_phases | Extracted current | There are 3 magnitudes |
| | in each of the 3 | measuring the change of |
| | phases | the phase currents after |
| | | each trigger. There are 3 |
| | | 15-cycle currents obtained |
| | | by deducting the average |
| | | current before the trigger |
| | | from the current after the |
| | | trigger. |
| Iextr | Extracted current | Magnitude measuring the |
| | in the residual | change of the residual |
| | current 3I0 | current 3I0 after each |
| | | trigger. It represent the |
| | | current of the new event |
| | | that causes the trigger |
| | | (possibly a HIF). It is a |
| | | 15-cycle current obtained |
| | | by deducting the average |
| | | current before the trigger |
| | | from 15-cycles of current |
| | | after the trigger. |
| THLD _{Sup}_Iextr | Superior threshold | Amplitude above which |
| | for Iextr | the Iextr is considered too |
| | | high for being the corre- |
| | | spondent to HIF current. |
| | | THLD _{Sup Iextr} ~150A |
| THLD _{Inf}_Iextr | Inferior threshold | Amplitude below which |
| | for Iextr | the Iextr is mostly noise, |
| | | so it will not be analysed. |
| | | THLD _{Inf Iextr} ~1A, 2A |
| Δt _{decision} | Period of time for | Time during which the |
| | taking the decision | information of the number |
| | | of triggers and the output of |
| | | the classifier is accumulated |
| | | so the decision can be done. |

The main condition for the good performance of the algorithm is that the residual current 3I0 during normal operation of the network is regular or not random, so that normal_AAD is low. Therefore, the value of normal_AAD has to be checked. If it is lower than a maximum randomness threshold value THLD normal_AAD then the residual current 3I0 is considered regular enough and the algorithm for triggering runs. Otherwise, the algorithm breaks, indicating that the load of the network is too random.

The value of normal_AAD is updated several times per day in order to be adapted to the changes in the network. So the algorithm will be aware of the moments when the conditions of the network are so bad that high-impedance fault detection cannot be done.

The algorithm is designed to trigger when there is a change in the residual current 3I0 linked to an increase of randomness. High-impedance faults cause changes in the residual current 3I0 and increase the randomness of the current, but also inrush currents or load switching activities do. The algorithm has to trigger in any of those cases, and later it will distinguish between high-impedance faults and other events.

There are two requirements for triggering: that the instantaneous value of AAD is higher than the threshold AAD_threshold and that the value of the instantaneous AAD is high enough so it indicates randomness. The AAD_threshold adapts its value each 5 cycles of current. If the instantaneous value of AAD passes this threshold, it means that the random of the residual current 3I0 at that moment has notably increased, because a change in the residual current 3I0 has occurred. On the other hand, the instantaneous value of AAD has to be representative, has to be higher than a minimum level of AAD that reveals randomness. This minimum level is rand_AAD, which is updated depending on the value of normal_AAD (further explanation in Table 1).

When a trigger is produced the algorithm extracts the component of the current related to the change that made the algorithm trigger (see step 120 in FIG. 2). This current component, Iextr, (hereinafter also referred to as average difference value Iextr) is analyzed in order to decide if it is related to a high-impedance fault or to another event. The algorithm also considers some other cases: the triggers related to 3-phase events, the very low amplitude extracted currents, and the too high amplitude extracted current.

If the trigger is due to a 3-phase event (see step 130 in FIG. 2), the event is not a high-impedance fault because high-impedance faults are single-phase faults. Therefore, after each trigger, the algorithm obtains the extracted currents in each of the 3 phases (ΔI in 3 phases). They are calculated by subtracting the phase current before the trigger from the phase current after the trigger. AI in 3 phases represents the 3-phase current of the event that causes the trigger. If the event is a single-phase-event, the extracted currents in two phases have to be negligible, and the extracted current in one phase has to be similar to the extracted current of the residual current 3I0, Iextr. On the contrary, if the extracted currents in the 3-phases have similar amplitudes, the event is a 3-phase event, so it is not a high-impedance fault and the algorithm breaks and outputs the label “No HIF”.

If the average difference value Iextr is higher than THLD sup_Iextr the output is “No HIF”. By definition, the amplitude of high-impedance faults is low, e.g. between 1 A and 70 A-100 A. In practice it needs to be considered that high-impedance fault detection is complementary to overcurrent protection, thus the maximum amplitude considered by high-impedance fault detection is the setting of the overcurrent protection. THLD sup_Iextr is given by the limit of the overcurrent protection of each network, and we estimate this value between 100 A and 200 A.

If the amplitude of Iextr is lower than THLD inf_Iextr, the algorithm memorizes the trigger by increasing a counter by “1” (see step 140 in FIG. 2), but the algorithm does not compute the classification of Iextr. Due to the inaccuracy of the current measurement and of the extraction method there is noise in Iextr. If the amplitude of Iextr is not much higher than the amplitude of the estimated noise, Iextr is considered too noisy to be analyzed. However, the fact that the algorithm triggered is taken into account is meaningful. In case the event analyzed is a high-impedance fault the algorithm will trigger several consecutive times during a long period, which can be several seconds or even days. Consequently, the information of the numbers of triggers during a period of time of decision is an input for deciding if the event is high-impedance fault or is not.

If the amplitude of Iextr is between THLD inf_Iextr and THLD sup_Iextr the algorithm memorizes the trigger by increasing the counter by “1”, and Iextr is classified as high-impedance fault or as “Other event” (see step 150 in FIG. 1).

In case the event is a high-impedance fault the extracted current Iextr is the current of the fault, so it would have the typical characteristics of high-impedance faults (main harmonic the 3rd harmonic, phase of the 3rd harmonic constant around 180°, effect of the arc at the current zero-crossing . . . ). Therefore, a given list of indicators (for instance 14 indicators as listed in the following Table 2) that reveal the typical characteristics of high-impedance faults may be calculated from the Iextr. Using this input, the classifier offers the output “HIF” or “Other event”. The output of the classifier is accumulated during the period of time Δt decision, and is used for taking the final decision. The following Table 2 lists indicators and their characteristics in an exemplary fashion:

| Indicators | Characteristics |
|---|---|
| rms_value | Typical amplitude and limit |
| | of algorithm |
| AADaverage | Randomness |
| Fast change | |
| Slow change | |
| Main Harmonic | 3^{rd} harmonic as main harmonic |
| Mean Amplitude of 3^{rd} H | component |
| Correlation 3^{rd} H/fund | Amplitude of 3^{rd} harmonic is |
| | not proportional to fundamental |
| | amplitude |
| Mean Phase 3^{rd} H | Constant phase of the third |
| Standard deviation | harmonic, close to 180° |
| of Phase 3^{rd} H | |
| Ratio 0 Cross | Effect of the arc at the |
| | current-zero-crossing |
| Min ADPN | Asymmetry between the negative |
| Mean ADPN | and positive part of the |
| Ratio Alternance | cycle |
| sign | |
| Ratio H3 | Asymmetry at the current- |
| | zero-crossing |

It is evident that more or less indicators or other types of indicators than those listed in Table 2 may be used. The list in Table 2 represents a preferred embodiment, only.

The decision logic (see step 160 in FIG. 2) indicates the final decision (“HIF”, “No HIF” or “Possible HIF”) based on the information of the numbers of triggers (see Table 2) and the output of the classifier during Δt decision (see steps 140 and 160 in FIG. 2). The output will be “HIF” if there were several triggers and a determined number of them were classified as high-impedance faults. The output will be “No HIF” if there were not enough triggers or if the number of them classified as “HIF” was lower than the minimum number needed for being suspicious of a high-impedance fault. And the output will be “Possible HIF” if there were several triggers and most of them were related to an Iextr lower than THLD inf_Iextr, or if the number of triggers classified as high-impedance fault was higher than the minimum number needed for being suspicious of a high-impedance fault but lower than the number that determines it as a high-impedance fault.

The extraction of the “suspicious event” as detailed above represents an important advantage compared to existing methods. By removing the component of the residual current that is due to the background load, the current of the event is obtained that has just appeared. So even if the current of the event is very low, it is extracted and analysed looking for characteristics of high-impedance faults.

The classification may be developed using data-mining techniques, and it can be improved as the database of residual currents in case of a high-impedance fault and residual currents in case of other suspicious events is extended. The classifier may be a one-class classifier using a Support Vector Machine. A Support Vector Machine may be trained and tested using a database of previous high-impedance faults and other events. Adding and removing data from the original database may be carried out to improve the classifier. An automatic system design for this function may be used. Some parameters such as normal_AAD and rand_AAD are specific for each network and each moment, so the method may adapt to the customer.

The design of the algorithm allows the possibility of future improvements that will be possible after testing the high-impedance fault detection method and increasing the training database. These improvements are related to the definition of THLDnormal_AAD, to the extraction algorithm and to the data-mining technique.

Instead of defining THLDnormal_AAD as a constant (C3=1E-3*spc*Nacc) it could depend on the amplitude of Iextr. Concerning the extraction method, the calculation of Iextr can be improved if the two currents that are subtracted (current before the trigger and after the trigger) are synchronized considering the possible error in frequency.

Related to the data-mining technique, the algorithm may use a one-class support vector machine with negative examples, but with a complete database it can be considered a two-class classification, such as random forest, decision rules . . . , etc.

1-13. (canceled)

14. A method for detecting a high-impedance fault occurring in an electric distribution circuit distributing a three-phase alternating current, which comprises the steps of:
applying a plurality of electrical signal analysis techniques for determining a plurality of fault detection indicators;
generating a signal indicating the high-impedance fault depending on an outcome of the fault detection indicators;
determining a randomness of a residual current of the three-phase alternating current prior to determining the plurality of fault detection indicators; and
generating a trigger signal depending on the randomness of the residual current, wherein the step of determining the plurality of fault detection indicators requires that the trigger signal has been generated.

15. The method of claim 14, which further comprises:
calculating a randomness value that describes the randomness of the residual current; and
generating the trigger signal depending on the randomness value.

16. The method according to claim 15, which further comprises calculating a first threshold value based on a given number of cycles that preceded an actual cycle, and wherein a generation of the trigger signal requires that the randomness value exceeds the first threshold value.

17. The method according to claim 16, which further comprises calculating a second threshold value that describes an average randomness of the residual current before an actual trigger cycle, a generation of the trigger signal requires that the randomness value exceeds the second threshold value.

18. The method according to claim 17, which further comprises generating the trigger signal if the randomness value exceeds the first and second threshold values.

19. The method according to claim 17, which further comprises generating the trigger signal if a reference value that indicates the average randomness of the residual current during normal conditions falls below a maximum randomness threshold value before an actual trigger cycle.

20. The method according to claim 19, which further comprises generating the trigger signal if the randomness value exceeds the first and second threshold values and the reference value falls below the maximum randomness threshold value.

21. The method according to claim 14, which further comprises:
evaluating an increase of each phase current of the three-phase alternating current in response to a generation of the trigger signal; and
determining that no high-impedance fault occurred if all three-phases of the three-phase alternating current exhibit a similar increase of current before or after the generation of the trigger signal.

22. The method according to claim 14, which further comprises calculating an average difference value by subtracting a previous average residual current value, that defines an average residual current before the generation of the trigger signal, from an actual residual current value that defines an average current after the generation of the trigger signal.

23. The method according to claim 22, which further comprises determining the plurality of fault detection indicators if the trigger signal has been generated and the average difference value is between a predefined lower threshold value and a predefined upper threshold value.

24. The method according to claim 23, which further comprises incrementing a counter if the trigger signal is generated and the average difference value exceeds the predefined upper threshold value.

25. The method according to claim 24, which further comprises determining the plurality of fault detection indicators if the trigger signal is generated and a counter reading equals or exceeds a predefined maximum count.

26. A high-impedance fault detector capable of detecting a high-impedance fault occurring in an electric distribution circuit distributing a three-phase alternating current, the high-impedance fault detector comprising:
computer programmed to carry out the steps of:
applying a plurality of electrical signal analysis techniques for determining a plurality of fault detection indicators;
generating a signal indicating a high-impedance fault in dependence on an outcome of the fault detection indicators;
determining a randomness of a residual current of the three-phase alternating current prior to determining the plurality of fault detection indicators;
generating a trigger signal depending on a randomness of the residual current; and
determining the plurality of fault detection indicators after the trigger signal has been generated.
